(19) United States
(12) Patent Application Publication
(10) Pub. No.: US 2018/0108455 A1
(43) Pub. Date: Apr. 19, 2018

(54) PARALLEL PAIR CABLE

(71) Applicant: SUMITOMO ELECTRIC INDUSTRIES, LTD., Osaka (JP)

(72) Inventor: Yuto KOBAYASHI, Kanuma-shi (JP)

(73) Assignee: SUMITOMO ELECTRIC INDUSTRIES, LTD., Osaka (JP)

(21) Appl. No.: 15/785,659

(22) Filed: Oct. 17, 2017

(30) Foreign Application Priority Data
Oct. 19, 2016 (JP) 2016-204800

(51) Int. Cl. H01B 11/00; H01B 7/02; H05K 9/00; C23C 18/31; C23C 16/50

(52) U.S. Cl. CPC H01B 11/002; H01B 7/0216; C23C 16/50; C23C 18/31; H05K 9/0098

(57) ABSTRACT

A parallel pair cable includes a pair of metal wires aligned in parallel at a predetermined interval, an insulating resin configured to integrally cover the pair of metal wires and having a cross-sectional shape of an ellipse, and a shield layer provided on an outer periphery of the insulating resin. The shield layer is a layer formed by plating or vapor-depositing metal on an outer peripheral surface of the insulating resin.

### CROSS-REFERENCE TO RELATED APPLICATION

The present application claims priority from Japanese Patent Application No. 2016-204800 filed on Oct. 19, 2016, the entire content of which is incorporated herein by reference.

### BACKGROUND

### Technical Field

The present invention relates to a parallel pair cable.

### Related Art

Patent Document 1 discloses a cable for differential signal transmission that includes a pair of conductive wires spaced and aligned in parallel, an insulator configured to cover the pair of conductive wires and having an outer periphery shape of a section in a width direction, which is a shape combined by a plurality of curves having different radii of curvature, and a metal foil tape wrapped on the insulator.
Patent Document 1: JP-A-2012-169251

The cable for differential signal transmission disclosed in Patent Document 1 has problems in that a wrapped state of the metal foil tape may be loosened or a wrapping wrinkle may occur. For this reason, the metal foil tape moves, so that a shield effect for the signal lines (the pair of conductive wires) becomes unstable and an output amount (Scd21) of a common mode relative to an input signal of a differential mode may increase. In addition, a rapid signal attenuation (dip) may occur in a high-frequency signal region.

### SUMMARY

Exemplary embodiments of the invention provide a parallel pair cable capable of reducing an output amount (Scd21) of a common mode relative to an input signal of a differential mode and preventing a rapid signal attenuation (dip) from occurring in a high-frequency signal region upon transmission of a differential signal.

A parallel pair cable according to an exemplary embodiment, comprises:

a pair of metal wires aligned in parallel at a predetermined interval;

an insulating resin configured to integrally cover the pair of metal wires and having a cross-sectional shape of an ellipse; and

a shield layer provided on an outer periphery of the insulating resin,

wherein the shield layer is a layer formed by plating or vapor-depositing metal on an outer peripheral surface of the insulating resin.

According to the exemplary embodiment, it is possible to reduce an output amount (Scd21) of a common mode relative to an input signal of a differential mode and to prevent a rapid signal attenuation (dip) region from occurring in a high-frequency signal region upon transmission of a differential signal.

### BRIEF DESCRIPTION OF THE DRAWINGS

FIG. 1 is a perspective view depicting a configuration of a parallel pair cable according to an exemplary embodiment.

FIG. 2 is a sectional view perpendicular to a longitudinal direction of the parallel pair cable of FIG. 1.

FIG. 3 is a sectional view perpendicular to a longitudinal direction of a parallel pair cable according to a modified embodiment of the exemplary embodiment.

### DETAILED DESCRIPTION

(Description of Exemplary Embodiment of Present Invention)

First, an exemplary embodiment of the present invention is described.

(1) A parallel pair cable according to an exemplary embodiment comprises:

a pair of metal wires aligned in parallel at a predetermined interval;

an insulating resin configured to integrally cover the pair of metal wires and having a cross-sectional shape of an ellipse; and

a shield layer provided on an outer periphery of the insulating resin,

wherein the shield layer is a layer formed by plating or vapor-depositing metal on an outer peripheral surface of the insulating resin.

According to the above configuration, since the shield layer is a layer formed by plating or vapor-depositing metal on the outer peripheral surface of the insulating resin, there are no concerns that a wrapped state is loosened or a wrapping wrinkle occurs, which occurs in the case of the metal foil tape. Thereby, it is possible to reduce an output amount (Scd21) of a common mode relative to an input signal of a differential mode and to prevent a rapid signal attenuation (dip) region from occurring in a high-frequency signal region upon transmission of a differential signal.

(2) The parallel pair cable further comprises:

an insulating jacket layer provided around the shield layer.

The insulating jacket layer is provided, so that it is possible to insulate the shield layer, to prevent the contamination from an outside and to provide the water-resistant cable.

### DETAILS OF EXEMPLARY EMBODIMENT OF PRESENT INVENTION

Hereinafter, a specific example of the parallel pair cable according to an exemplary embodiment of the present invention will be described with reference to the drawings.

In the meantime, the present invention is not limited to the example, is defined in the claims and includes all changes within meanings and ranges equivalent to the claims.

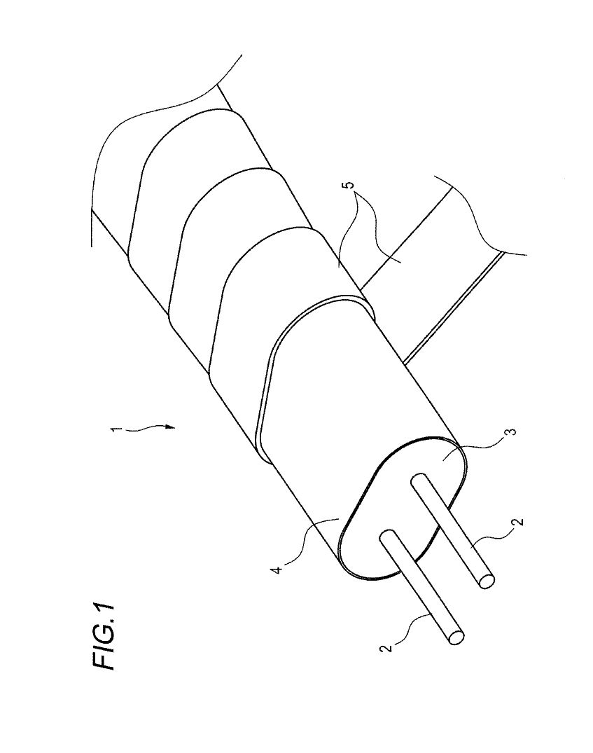

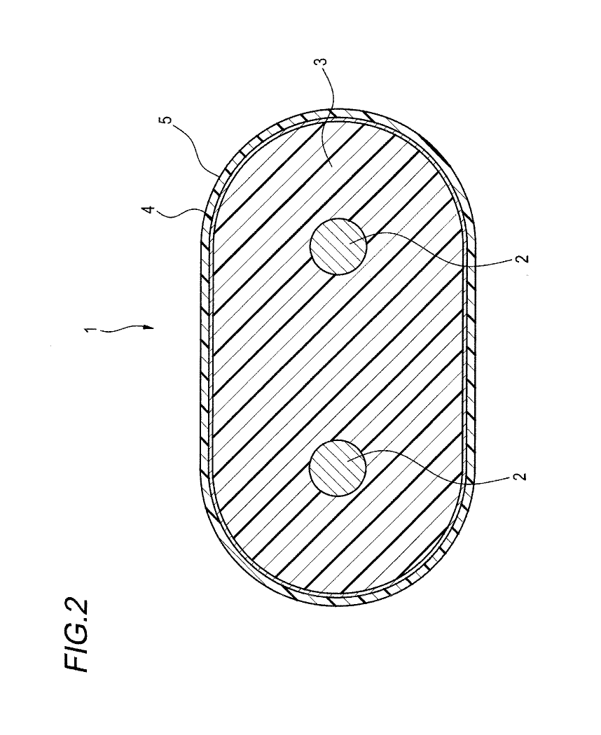

As shown in FIGS. 1 and 2, a parallel pair cable 1 includes a pair of metal wires 2 aligned in parallel at a predetermined interval and an insulating resin 3 configured to integrally cover the pair of metal wires 2. In addition, the parallel pair cable 1 includes a shield layer 4 provided on an outer periphery of the insulating resin 3 and a jacket layer 5 provided around the shield layer 4.

The metal wire 2 is a single wire or a stranded wire formed of a conductor such as copper, aluminum, alloy including copper and aluminum as main components, or the like or a conductor plated with tin, silver or the like. A size of the conductor used for the metal wire 2 is AWG38 to AWG22 on the basis of AWG (American Wire Gauge) standards. A distance between centers of the pair of metal wires 2 is preferably 0.5 to 5 times as large as a conductor diameter.

The insulating resin 3 is formed of a thermoplastic resin having a low dielectric constant such as polyethylene (PE), polypropylene (PP) or the like. The insulating resin 3 is supplied from an extruder and covered to the pair of metal wires 2. The insulating resin 3 has an elliptical shape, for example, as seen from a cross-section. An aspect ratio of the insulating resin 3 is preferably a width 1.2 to 2.5 relative to a height 1. On the other hand, the insulating resin 3 may be extruded and coated using a thermoplastic resin such as polyethylene, polyvinyl chloride (PVC), fluorine resin or the like. The insulating resin 3 may be a solid layer. Alternatively, the insulating resin 3 may be a foamed layer. The foamed layer is preferable because it has a dielectric constant smaller than the solid layer. In the case of the foamed layer, a residual diameter ratio (a value obtained by dividing a diameter of the insulating resin in a crushing direction after deformation by a diameter of the insulating resin before deformation when an external force is applied to the insulating resin) of the insulating resin when load of 1 kg is applied for 30 minutes is preferably 80% to 99%.

Meanwhile, in the specification, the term “cross-section” means a section seen from a longitudinal direction of the parallel pair cable. Also, the term “ellipse” means a shape including an elliptical shape, an oval shape obtained by flattening a circular shape, a shape obtained by connecting two parallel lines into a circular arc-shaped curve, and the like.

The shield layer 4 is a metal layer formed on the outer peripheral surface of the insulating resin 3 by plating or vapor-deposition. The shield layer 4 is plated or vapor-deposited to be directly attached to the insulating resin 3 without another member such as an adhesive or a resin tape. As the metal of the shield layer 4, steel, aluminum, silver, nickel or the like is used.

As the metal plating method, an electroless plating method and the like are used. In the electroless plating, a palladium catalyst or the like may be used depending on a material to be plated. Also, as the metal vapor-depositing method, a physical vapor deposition method such as a vacuum vapor deposition method, a chemical vapor deposition method such as a thermal chemical vapor deposition (CVD) method and a plasma CVD method, and the like may be used.

A thickness of the shield layer 4 is preferably 0.1 μm to 10 μm. In general, when a thickness of the metal layer is thin (for example, 1 μm or less), the metal layer is obtained by the vapor deposition, and when a thickness of the metal layer is thick, the metal layer is obtained by the plating. Depending on uses of the parallel pair cable 1, a favorable thickness of the shield layer 4 is determined, and the plating or vapor deposition method is appropriately selected.

The jacket layer 5 is an insulting layer configured to cover the shield layer 4, and is formed of a resin tape such as polyethylene terephthalate (PET), polyvinyl chloride (PVC), polyethylene or the like. The resin tape configuring the jacket layer 5 is preferably spirally wrapped (helically wrapped) around the shield tape 4, for example. In the example of FIGS. 1 and 2, the jacket layer 5 is formed by wrapping one resin tape. However, a plurality of resin tapes may be wrapped. In FIG. 2, the overlapping portions of the tape are omitted. For example, the jacket layer may be formed by doubly wrapping two resin tapes. When the two resin tapes are wrapped, the wrapping directions may be the same or may be opposite to each other. When the tapes of the jacket layer 5 are wrapped in the same direction, the flexibility of the cable is favorable, and when the tapes are wrapped in the opposite directions, torsional deformation hardly occurs in the cable. In the meantime, the jacket layer 5 may be formed by extruding a thermoplastic resin such as polyethylene, polyvinyl chloride, fluorine resin or the like.

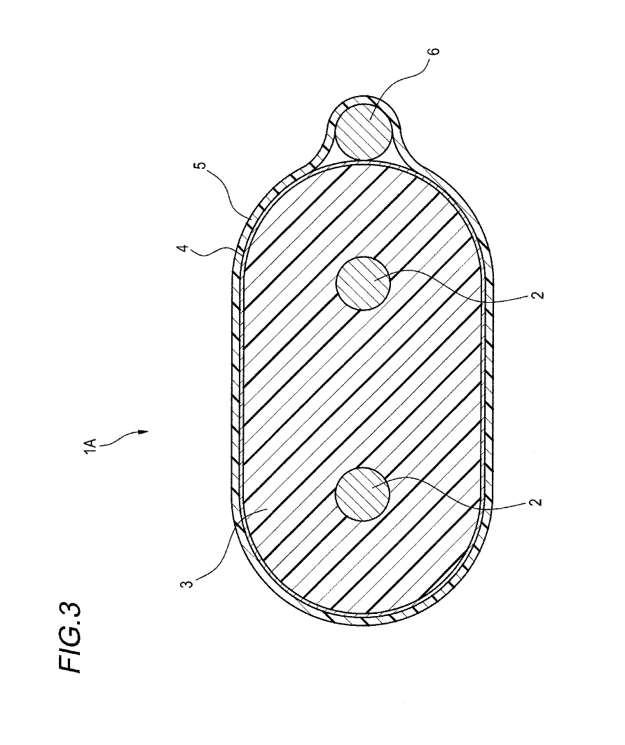

Also, like a parallel pair cable 1A (refer to FIG. 3) according to a modified embodiment of the exemplary embodiment, when a drain wire 6 (a metal wire such as a copper wire) is disposed between the jacket layer 5 and the shield layer 4, the shield layer 4 can be grounded by connecting the drain wire 6 to a ground terminal of a substrate or a connector. Thereby, it is possible to easily perform the connection processing of the parallel pair cable. In the example of FIG. 3, the two metal wires 2 and the drain wire 6 are laterally disposed. Two drain wires may be laterally disposed at the both sides of the shield layer 4. However, the drain wire 6 can be disposed at any position inasmuch as it is disposed between the jacket layer 5 and the shield layer 4 (for example, a position above or below the metal wires 2). Also, the number of the drain wire 6 may be one or more.

Subsequently, a manufacturing method of the parallel pair cable 1 is described.

First, the two metal wires 2 are disposed in parallel at a predetermined interval. Then, the pair of metal wires 2 is covered by extruding foamed polyethylene, for example, so that the insulating resin 3 of which a cross-sectional shape is an ellipse is formed.

Subsequently, the metal plating or metal vapor deposition is performed on the outer peripheral surface of the insulating resin 3, so that the shield layer 4 made of metal such as copper, aluminum, silver, nickel or the like is formed. Then, the resin tape is spirally wrapped around the shield layer 4, so that the insulating jacket layer 5 is formed. Thereby, the parallel pair cable 1 having the metal layer (the shield layer 4) integrated with the insulating resin 3 is manufactured.

According to the parallel pair cable 1 having the above configuration, since the shield layer 4 is a layer formed by plating or vapor-depositing metal on the outer peripheral surface of the insulating resin 3, there is no trouble owing to a shield metal foil tape wrapped on the outer periphery of the insulating resin 3. Thereby, it is possible to reduce an output amount (Scd21) of a common mode relative to an input signal of a differential mode and to prevent a rapid signal attenuation (dip) region from occurring in a high-frequency signal region upon transmission of a differential signal, as compared to the case in which the shield tape is wrapped around the insulating resin.

In addition, since the insulating jacket layer 5 is provided around the shield layer 4, it is possible to insulate the shield layer 4, to prevent the contamination from an outside and to provide the water-resistant parallel pair cable 1. When the jacket layer 5 is formed by a plurality of resin tapes, for example, when the jacket layer is formed by spirally wrapping the two resin tapes in the opposite directions, it is possible to further increase the insulation of the shield layer 4 and the water resistance of the parallel pair cable 1.

### EXAMPLES

The measurement results of the mode conversion amount (Scd21) and the dip (suck-out phenomenon) for the parallel pair cables of Examples and Comparative examples are described.

In the meantime, Scd21 indicates a conversion amount from a differential mode to a common mode from Port 1 to Port 2, and is one of mixed mode S parameters. In a compliance test of a USB cable (for example, USB 3.0), Scd21 is set to −20 dB/m or less. Also, the dip indicates that a frequency characteristic of a signal attenuation amount is rapidly decreased in a frequency band about 20 GHz.

In the measurement, when a high-frequency signal of 20 GHz or higher was transmitted to the parallel pair cable having a length 3 m, the parallel pair cable of which a maximum value of the Scd21 value was −20 dB/m or smaller was determined as favorable, and the parallel pair cable of which the maximum value was −25 dB/m or smaller was determined as excellent. Also, the parallel pair cable of which the maximum value of the Scd21 value was greater than −20 dB/m was determined as defective. Also, it was checked whether the dip occurred or not.

### Example 1

The parallel pair cable of Example 1 had the configuration shown in FIGS. 1 and 2, and was prepared as follows.

The two metal wires 2 of AWG30 (an outer diameter 0.29 mm) were aligned in parallel at an interval of 1.2 mm, and were covered with foamed polyethylene (the insulated resin 3) by the extrusion. The insulating resin 3 was formed to have a cross-sectional shape of an oval shape. The shield layer 4 having a thickness of 1 μm was formed on the outer peripheral surface of the insulating resin 3 by vapor depositing copper with the vacuum vapor deposition method. In FIGS. 1 and 2, the jacket layer 5 is formed by one resin tape. However, in Example 1, the jacket layer 5 was formed by spirally wrapping the two the resin tapes in the opposite directions.

The parallel pair cable of Example 1 was made to have a length 3 m, the high-frequency signal of 20 GHz or higher was transmitted, and Scd21 and the dip were measured.

As a result of the measurement, the maximum value of the Scd21 value was −25 dB/m or less, so that the quality of the parallel pair cable of Example 1 was determined as excellent. In addition, the dip did not occur up to the frequency band of 25 GHz.

### Comparative Example 1

The shield layer was formed by spirally wrapping a PET tape (metal foil tape) provided on the metal layer of copper around the insulating resin. The thickness of the metal layer of copper was 6 μm, and the thickness of the PET tape was 9 μm. The other configurations were similar to Example 1.

The parallel pair cable of Comparative example 1 was made to have a length 3 m, the high-frequency signal of 20 GHz or higher was transmitted, and Scd21 and the dip were measured.

As a result of the measurement, the maximum value of the Scd21 value was greater than −20 dB/m, so that the quality of the parallel pair cable of Comparative example 1 was determined as defective. In addition, the dip occurred in the frequency band of 20 GHz to 25 GHz. This is considered to be due to the loosening or wrapping wrinkle occurred in the metal foil tape spirally wrapped around the insulating resin.

### Comparative Example 2

The shield layer was formed by longitudinally wrapping a PET tape (metal foil tape) provided on the metal layer of copper around the insulating resin. The thickness of the metal layer of copper was 6 μm, and the thickness of the PET tape was 9 μm. The other configurations were similar to Example 1.

The parallel pair cable of Comparative example 2 was made to have a length 3 m, the high-frequency signal of 20 GHz or higher was transmitted, and Scd21 and the dip were measured.

As a result of the measurement, the maximum value of the Scd21 value was greater than −20 dB/m, so that the quality of the parallel pair cable of Comparative example 1 was determined as defective. In addition, the dip occurred in the frequency band of 20 GHz to 25 GHz. This is considered to be due to the loosening or wrapping wrinkle occurred in the metal foil tape longitudinally wrapped around the insulating resin.

Although the present invention has been described in detail with reference to the specific exemplary embodiments, it is obvious to one skilled in the art that various changes and modifications can be made without departing from the spirit and scope of the present invention. Also, the number, positions, shapes and the like of the constitutional members described above are not limited to the exemplary embodiments, and can be changed to the number, positions, shapes and the like suitable for implementation of the present invention.

What is claimed is:

1. A parallel pair cable comprising:
a pair of metal wires aligned in parallel at a predetermined interval;
an insulating resin configured to integrally cover the pair of metal wires and having a cross-sectional shape of an ellipse; and
a shield layer provided on an outer periphery of the insulating resin,
wherein the shield layer is a layer formed by plating or vapor-depositing metal on an outer peripheral surface of the insulating resin.

2. The parallel pair cable according to claim 1, further comprising:
an insulating jacket layer provided around the shield layer.
